(19) United States
(12) Patent Application Publication
(10) Pub. No.: US 2011/0085314 A1
(43) Pub. Date: Apr. 14, 2011

(54) ELECTRICAL CIRCUIT SYSTEM AND METHOD FOR PRODUCING AN ELECTRICAL CIRCUIT SYSTEM

(76) Inventor: Michael Franz, Reutlingen (DE)

(21) Appl. No.: 12/672,842

(22) PCT Filed: Jul. 10, 2008
(86) PCT No.: PCT/EP2008/058959

§ 371 Date: Dec. 15, 2010

(30) Foreign Application Priority Data
Aug. 16, 2007 (DE) 10 2007 038 514.7

(51) Int. Cl. H05K 1/14; H01R 43/00

(52) U.S. Cl. 361/803; 29/825

(57) ABSTRACT

An electrical circuit system includes at least one first circuit device and at least one second circuit device, the two circuit devices being electrically connected to one another by interconnecting at least one transfer device. The transfer device is electrically connected to the first circuit device by conductive adhesive bonds, and the transfer device is electrically connected to the second circuit device by conductive adhesive bonds and/or solder joints. Furthermore, a method for producing a corresponding electrical circuit system.

### FIELD OF THE INVENTION

The present invention relates to an electrical circuit system having at least one first circuit device and at least one second circuit device, the circuit devices being electrically connected to one another by interconnecting at least one transfer device. Furthermore, the present invention relates to a method for producing an electrical circuit system, which includes at least one first circuit device and at least one second circuit device, at least one transfer device being situated between the circuit devices for the electrical connection of the circuit devices, and the circuit devices being electrically connected to the transfer device.

### BACKGROUND INFORMATION

Circuit systems having two circuit devices are known as electronic devices having different functions, for example. In general, the electronic devices are made up of a first circuit device implemented as control electronics, and a second circuit device implemented as power electronics. The control electronics and the power electronics are often based on different circuit technologies. Most electrical and mechanical connection concepts of control electronics and power electronics provide a planar assembly. When utilizing circuit devices based on different technologies, the different assembly concepts for the most part are realized electrically and/or mechanically by plugs, cables, pressed screens, bonds, flex-circuit boards and/or other electrical connection means. These conventional assembly concepts require additional installation space for the wiring in connection with the electrical connection of the first circuit device to the second circuit device.

### SUMMARY OF THE INVENTION

For the uncomplicated assembly and space-saving electrical connecting/contacting of the circuit devices with the aid of at least one transfer device, the transfer device is electrically connected to the first circuit device with the aid of conductive adhesive bonds, and the transfer device is electrically connected to the second circuit device by conductive adhesive bonds and/or solder joints. The two circuit devices include contact areas for the electrical interconnection, which are electrically connected to one another via the transfer device. For this purpose the transfer device has a corresponding electrical connection structure, which electrically connects the contact areas of the first circuit device to the corresponding associated contact areas of the second circuit device. For this, the transfer device is provided with contact areas as well. The contact areas of the first circuit device are electrically connected to associated contact areas of the transfer device by conductive adhesive bonds. The contact areas of the second circuit device are electrically connected to associated contact areas of the transfer device by conductive adhesive bonds and/or solder joints. The contact areas of the transfer device assigned to the contact areas of the first circuit device are connected to the contact areas of the transfer device assigned to the contact areas of the second circuit device via an electrical connection structure of the transfer device, such that, following the assembly, the contact areas of the first circuit device are electrically connected to the associated contact areas of the second circuit device. The material of the connections of the first circuit device to the transfer device or the transfer device to the second circuit device may differ or match. Prior to producing the individual connections, the particular material for forming the connections is preferably present in the form of a paste.

The transfer device is preferably designed in such a way that it connects the circuit devices mechanically as well, thereby producing a compact and stable electrical circuit system. In addition, in one advantageous development of the present invention, at least one additional transfer device and/or at least one transfer element are/is provided for the electrical and/or mechanical connection of the circuit devices.

In one advantageous development of the present invention, the transfer device is provided with the conductive adhesive bonds for the connection to the first circuit device on its upper side, and with the conductive adhesive bonds and/or solder joints for the connection to the second circuit device on its bottom side. Regardless of the actual orientation of the transfer device, the two sides are two sides of the transfer device that lie opposite one another.

In an advantageous manner, the transfer device is a transfer board or includes at least one transfer board. The transfer device has n layers, with n=1, 2, 3, . . . .

Moreover, the first circuit device advantageously is a first circuit board or includes at least one first circuit board. The first circuit device has m layers, with m=1, 2, 3, . . . .

In one advantageous development of the present invention, the second circuit device is a second circuit board or includes at least one second circuit board. The second circuit device has o layers, with o=1, 2, 3, . . . .

According to one further refinement of the present invention, the first circuit device is realized on the basis of a first circuit board technology. Preferably, the first circuit device is implemented based on conventional technology using a circuit board, or implemented in LTCC technology (low temperature co-fired ceramic) using an LTCC substrate.

Furthermore, it is advantageously provided that the second circuit device is implemented in a second circuit board technology. The second circuit device is preferably realized in DCB technology (DCB: direct copper bonded) using DCB substrate.

In particular, it is provided that the first circuit device is a low-current circuit device, and/or that the second circuit device is a high-current circuit device. In connection with this application, a low-current circuit device is a circuit device whose power consumption is so low that the current-carrying capacity of the conductive connection medium, i.e., the conductive adhesive agent, is not exceeded. In the context of this application, a high-current circuit device is a circuit device whose power consumption is so high—at least in at least one operating situation—that the current-carrying capacity of the conductive connection medium (the conductive adhesive agent and/or the solder paste) is not exceeded.

Preferably, the conductive adhesive bonds are formed by conductive adhesive agents, in particular imprinted conductive adhesive agents. For the electrical connection of the first circuit device to the transfer device, the conductive adhesive agent is preferably imprinted on the contact areas of the first circuit device and/or on the transfer device, and for the electrical connection of the second circuit device to the transfer device, it is preferably imprinted on the contact areas of the second circuit device and/or on the transfer device.

Finally, it is advantageously provided that the solder joints are formed by solder paste, especially imprinted solder paste. Prior to the assembly of the transfer device and the second circuit device, the contact areas of the transfer device and/or the second circuit device are imprinted with solder paste and subsequently soldered to one another.

The two circuit devices and the transfer device are advantageously joined to one another mechanically using an electrically insulating filler material (underfill), so that the electrical circuit system is realized in the form of an electrical circuit module. Such an underfill is known from SMD technology.

The method according to the present invention is characterized by the electrical connection of the transfer device to the first circuit device with the aid of an adhesive agent, and the electrical connection of the transfer device to the second circuit device with the aid of conductive adhesive bonds and/or solder joints. For a circuit system having two circuit devices, the following production steps preferably result:
Imprinting the transfer device with solder paste on its second side;
Soldering the transfer device to the second circuit device, whereupon it is possible to conduct a first function test;
Imprinting the first side of the transfer device with conductive adhesive;
Bonding the system (intermediate module) made up of transfer device and second circuit device to the first circuit device, whereupon it is possible to conduct a function test of the entire circuit system; and
Introducing a filler material (underfill) in order to increase the mechanical stability of the module.

### BRIEF DESCRIPTION OF THE DRAWINGS

FIG. 1 shows a first circuit device, a second circuit device, and a transfer device.

FIG. 2 shows the transfer device imprinted with solder paste.

FIG. 3 shows an intermediate module made up of transfer device and second circuit device joined to it by soldering.

FIG. 4 shows the intermediate module shown in FIG. 3, made up of the second circuit device and transfer device, whose upper side is imprinted with conductive adhesive.

FIG. 5 shows an electrical circuit system made up of the first circuit device, the transfer device, and the second circuit device.

FIG. 6 shows the circuit system of FIG. 5 with an underfill for mechanical stabilization.

FIG. 7 shows thermal contacting of the circuit system at a heat sink.

### DETAILED DESCRIPTION

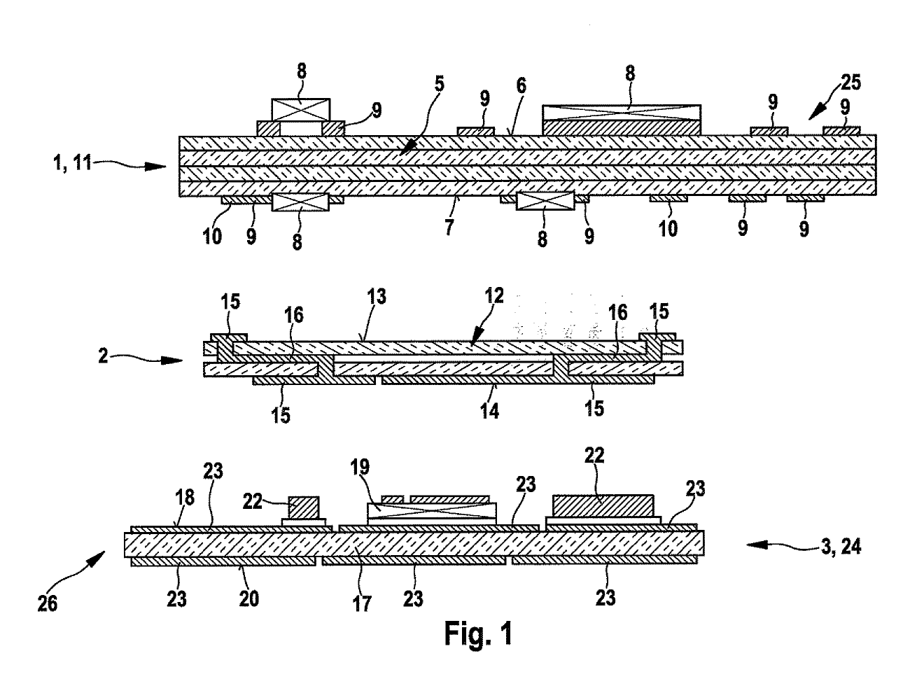

FIG. 1 shows a first circuit device 1, a transfer device 2, and a second circuit device 3 prior to an electrical connection to a circuit system 4. This circuit system 4 is part of an electric device, in particular.

First circuit device 1 is formed by a first circuit board 5 realized by m layers, m=4. Situated on upper side 6 and also on bottom side 7 of first circuit device 1 are electrical components 8, especially electronic components, contacted with circuit traces 9 (shown only partially) of first circuit device 1. The different layers of first circuit device 1 are electrically contacted with one another by plated-through holes (not shown) implemented as vias. On its bottom side 7, first circuit device 1 has a plurality of contact areas 10, which are used in the assembled circuit system for bringing first circuit device 1 into contact with transfer device 2. The first circuit device is implemented as low-current circuit device 11.

Transfer device 2 is formed by a transfer board 12 having n layers, n=2, which has individual contact areas 15 on its first side 13 developed as upper side 13, and on its second side 14 developed as bottom side 14. Contact areas 15 are electrically interconnected by circuit traces 16 of transfer device 2. The connections are connections between contact areas 15 on upper side 13, connections between contact areas 15 on bottom side 14, and connections between contact areas 15 of upper side 13 and bottom side 14. Contact areas 15 on upper side 13 of transfer device 2 are disposed in such a way that they are situated congruently with associated contact areas 10 on bottom side 8 of first circuit device 1 in a mounting position.

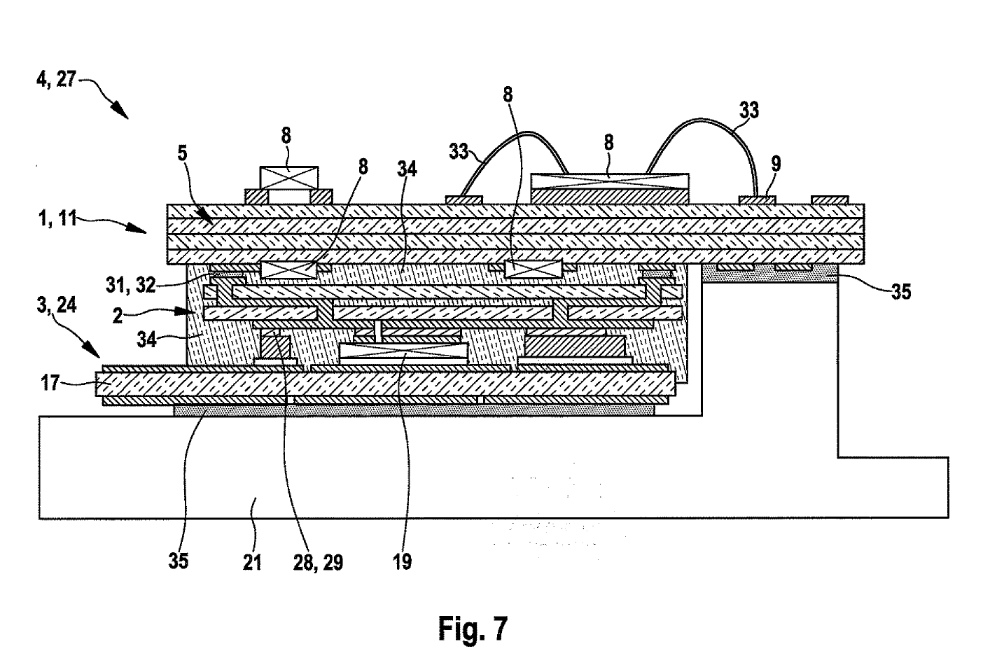

Second circuit device 3 is formed by a second circuit board 17 having o layers, o=1. Second circuit device 3 is provided with electrical components 19, especially electronic components, on its upper side 18. In this exemplary embodiment, a bottom side 20 of second circuit device 3 is free of electrical components 19 and, for example, may be utilized for the thermal contacting of a heat sink 21 shown in FIG. 7. Electrical components 19 of second device 3 are electrically connected to each other and to contact areas 22 on upper side 18 of second circuit device 3 with the aid of circuit traces 23. Contact areas 22 of second circuit device 3 are placed in such a way that they are situated congruently with contact areas 15 on bottom side 14 of transfer device 2 in a mounting position. Via contact areas 22 of second circuit device 3 and contact areas 15 on bottom side 14 of transfer device 2, second circuit device 3 and transfer device 2 are electrically contacted with one another once circuit system 4 has been assembled. Second circuit device 3 is a high-current circuit device 24.

Electrical components 8, 19 are at least partially electronic components, especially SMD components. First circuit device 1 forms control electronics 25 within the completely mounted circuit system 4, and second circuit device 3 forms power electronics 26 in completely assembled circuit system 4.

Accordingly, electrical components 8 of first circuit device 1 are elements of control electronics 25, and electrical components 19 of second circuit device 3 are power components of power electronics 26. These electrical components 19 of second circuit device 3 are at least partially power semiconductors without housing and provided with corresponding electrical connections.

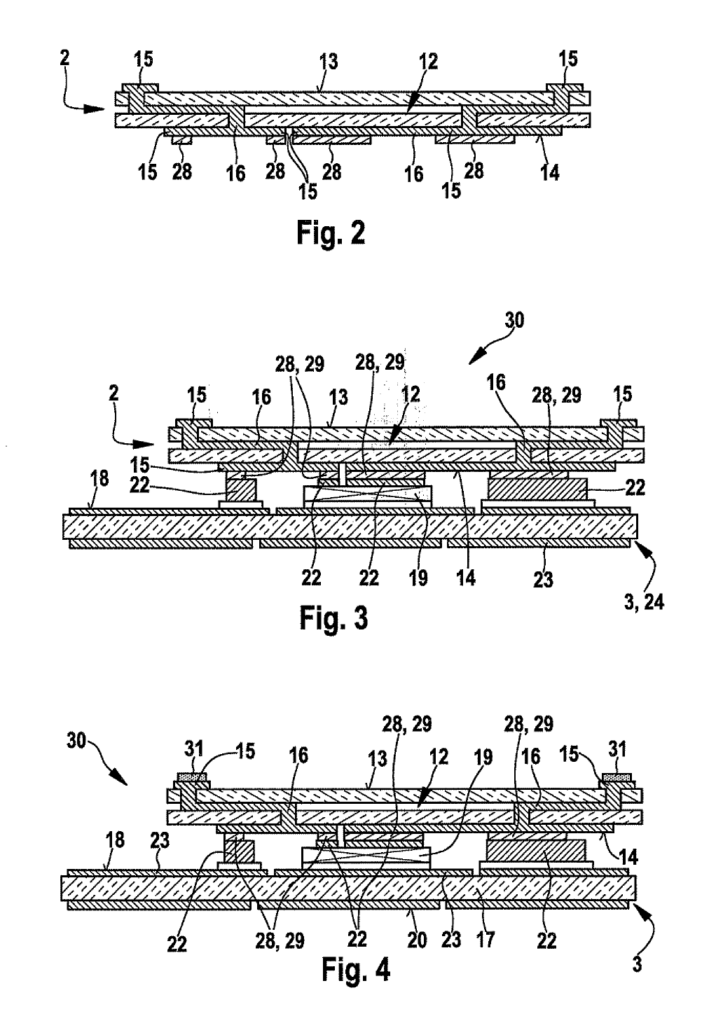

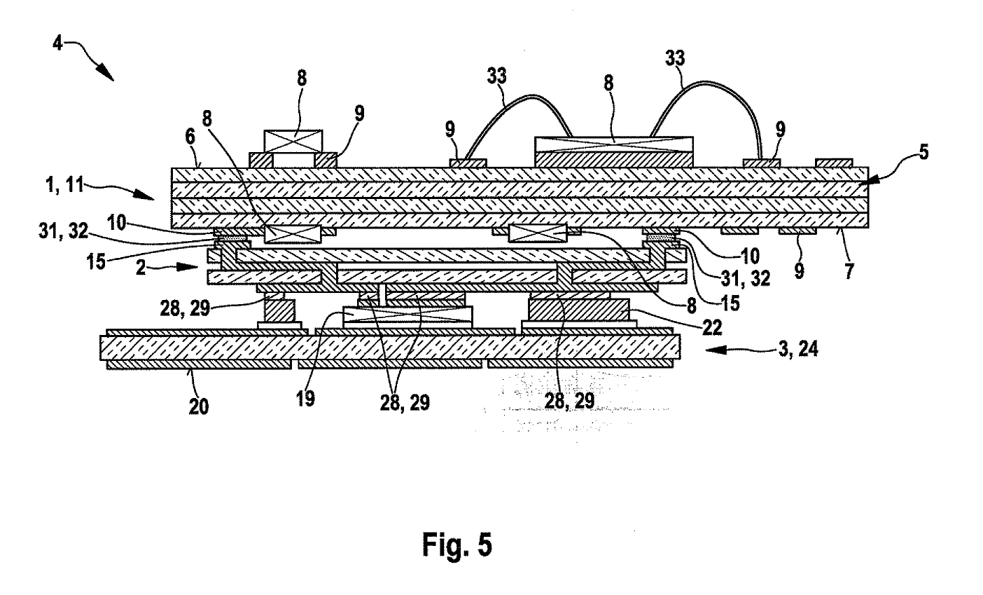

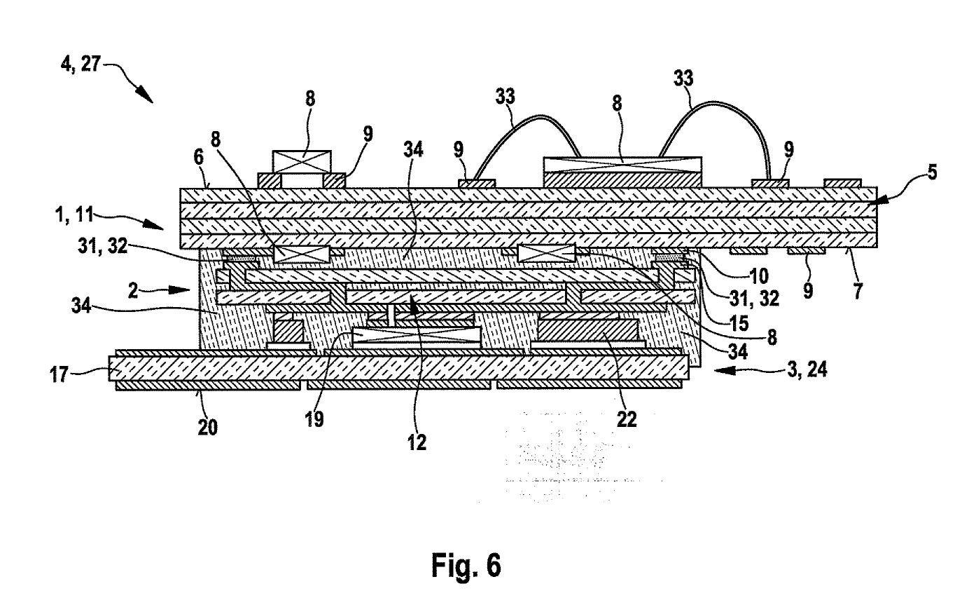

In the following text, FIGS. 2 through 7 describe an assembly sequence of an assembly of circuit system 4 made up of first circuit device 1, transfer device 2, and second circuit device 3. The assembly produces a circuit system 4 designed as three-dimensional multi-layer circuit system 27, which is shown in FIGS. 6 and 7. The assembly sequence is as follows:
1. Imprinting bottom side 14 of transfer device 2 with solder paste 28. FIG. 2 shows a corresponding transfer device 2 whose contact areas 15 on bottom side 14 are imprinted with solder paste 28.
2. Soldering transfer device 2 to second circuit device 3. FIG. 3 shows devices 2, 3 electrically contacted to one another via contact areas 15, 22 of transfer device 2 and second circuit device 3, as well as solder joints 29 formed by solder paste 28. This results in an intermediate module 30 made up of these devices 2, 3. Following this first contacting of transfer device 2 with second circuit device 3, a first function text of this module 30 is able to be performed.
3. Imprinting contact areas 15 on upper side 13 of transfer device 2 with conductive adhesive 31. FIG. 4 shows module 30 illustrated in FIG. 3, in which contact areas 15 on upper side 13 of transfer device 2 have been imprinted with conductive adhesive 31 for the electrical contacting with first circuit device 1 (not shown).
4. Bonding module 30 to first circuit device 1 using conductive adhesive 31 for the electrical contacting of module 30 with first circuit device 1. FIG. 5 shows circuit system 4 made up of first circuit device 1, transfer device 2 and second circuit device 3. In comparison with module 30 shown in FIGS. 3 and 4, contact areas 10 of the first circuit device have been bonded to contact areas 15 of transfer device 2 for the electrical contacting. Components 8 on upper side 6 of first circuit system 1 are contacted with circuit traces 9 by means of bonds 33.

To increase the mechanical stability of circuit system 4 implemented as three-dimensional multi-layer circuit system 27, an electrically insulating underfill 34, which at least partially surrounds transfer device 2, is introduced between first circuit device 1 and second circuit device 3. Such an underfill 34 is known from surface mounting as implemented in SMD technology, for example. Then, a final function test of circuit system 4 may be performed.

Once underfill 34 has been introduced, three-dimensional multi-layer circuit system 27 is able to be installed in a housing, and the external contacting of circuit system 4 may be implemented. In the process, at least one of circuit devices 1, 3 is brought into thermal contact with a cooling body 21, preferably via heat-conducting paste 35 (FIG. 7).

The following specific embodiments result: all types of module frames, e.g., STD substrate, LTCC (low-temperature confired ceramic), direct copper bonded (DCB) substrate, conventional circuit boards, are suitable as circuit boards 5, 12, 17.

In addition, the following advantages are obtained:
Dispensing with space-requiring connection elements such as plugs, cables, pressed screens, bonds, flex circuit boards, for example.
Combining solder and conductive adhesive mounting for the interconnection of control electronics and power electronics 25, 26.

In the process, solder joints 29 are used for the high current area or power electronics 26, and conductive adhesive bond 32 for the low current area or control electronics 25.

The use of transfer device 2 makes it possible to combine the mounting techniques of soldering and adhesive bonding. Transfer device 2 assumes the following tasks:
The electrical contacting (“wiring”) of first and second circuit devices 1, 3;
The thermal separation of first and second circuit devices 1, 3, which is advantageous in particular for a high-current circuit device 24 and a low-current circuit device 11;
Compensation of material stresses between the first and second circuit device; and
Separation of the regions of solder joints 29 from the regions of conductive adhesive connection 32, conductive adhesive 31 and underfill 34 being able to be introduced in addition.

In an especially preferred manner, each device (first circuit device 1, transfer device 2, and second circuit device 3) is first processed using its particular technology (conventional circuit board, LTCC, DBC, . . . ), each device 1, 2, 3 as such being able to be constructed on a large substrate, tested and subsequently separated.

As an alternative to the illustrated circuit system 4 having two circuit devices 1, 3 and a transfer device 2, circuit system 4 may also have more than two circuit devices, which are electrically connected/contacted with one another by at least two transfer devices. Preferably only the conductive connections of a transfer device are implemented as solder joints.

1-10. (canceled)

11. An electrical circuit system comprising:
at least one first circuit device;
at least one second circuit device; and
at least one transfer device interconnected to the first and second circuit devices to electrically connect the first and second circuit devices to one another, the transfer device being electrically connected to the first circuit device by conductive adhesive bonds, the transfer device being electrically connected to the second circuit device by at least one of (a) conductive adhesive bonds and (b) solder joints.

12. The circuit system according to claim 11, wherein the transfer device has on its upper side the conductive adhesive bonds for connecting to the first circuit device, and on its bottom side it has the at least one of (a) the conductive adhesive bonds and (b) the solder joints for connecting with the second circuit device.

13. The circuit system according to claim 11, wherein the transfer device includes at least one transfer board.

14. The circuit system according to claim 11, wherein the first circuit device includes at least one first circuit board.

15. The circuit system according to claim 11, wherein the second circuit device includes at least one second circuit board.

16. The circuit system according to claim 11, wherein the first circuit device is implemented in a first circuit board technology.

17. The circuit system according to claim 11, wherein the second circuit device is implemented in a second circuit board technology.

18. The circuit system according to claim 11, wherein the conductive adhesive bonds are formed by imprinted conductive adhesive.

19. The circuit system according to claim 11, wherein the solder joints are formed by imprinted solder paste.

20. A method for producing an electrical circuit system, the circuit system including at least one first circuit device and at least one second circuit device, and at least one transfer device situated between the circuit devices for an electrical connection of the circuit devices, the circuit devices being electrically connected to the transfer device, the method comprising:
electrically connecting the transfer device to the first circuit device by conductive adhesive; and
electrically connecting the transfer device to the second circuit device with the aid of at least one of (a) conductive adhesive bonds and (b) solder joints.
